(19) United States
(12) Patent Application Publication
(10) Pub. No.: US 2026/0168083 A1
(43) Pub. Date: Jun. 18, 2026

(54) Patterned DLC Coating for High Temperature Electrostatic Chucks

(71) Applicant: Applied Materials, Inc., Santa Clara, CA (US)

(72) Inventors: Dawei Sun, Lynnfield, MA (US); Eric D. Hermanson, Georgetown, MA (US)

(21) Appl. No.: 18/979,741

(22) Filed: Dec. 13, 2024

(51) Int. Cl. C23C 16/04; C23C 16/27; H02N 13/00

(52) U.S. Cl. CPC C23C 16/042; C23C 16/276; H02N 13/00

(57) ABSTRACT

A method of preparing an electrostatic platen is disclosed. At high temperatures, some low friction coatings, such as diamond like carbon (DLC), become conductive. The methods described allow the deposition of a limited amount of DLC to those regions of the electrostatic platen that contact the workpiece. By limiting the amount of DLC applied to the electrostatic platen, the clamping force experienced by the workpiece is minimally affected by the increased conductivity of the DLC at elevated temperatures. The DLC is applied to embossments that extend upward from the flat surface of the electrostatic platen.

### FIELD

Embodiments of the present disclosure relate to methods for coating an electrostatic chuck to ensure adequate clamping at elevated temperatures.

### BACKGROUND

Semiconductor devices are fabricated using a plurality of processes, including etching, implanting, and amorphization. In some of these processes, the workpiece may be disposed on a platen, which provides an electrostatic force so as to clamp the workpiece in place. This electrostatic force is generated by electrodes disposed in the platen, which are energized in a specific sequence to provide the clamping force. This clamping force also relies on a workpiece that is conductive, and a dielectric layer located in the platen that is disposed between the electrodes and the workpiece.

In some embodiments, one or more coatings are disposed on top of the dielectric layer of the platen to create a smoother surface and minimize the possibility of diffusion of metals from the dielectric layer to the workpiece. One such coating that may be used is diamond like carbon (DLC). This material is useful as it is a low friction material, and therefore reduces the generation of particles when the workpiece is placed on and removed from the platen. Further, this material is not conductive, and therefore does not affect the clamping of the workpiece.

However, it has been found that at elevated temperatures, such as greater than 500°C, the structure of DLC begins to change, causing it to become more conductive. As the DLC becomes more conductive, the clamping force that interacts with the workpiece is reduced. In some embodiments, the clamping force may be diminished to the point that the workpiece is no longer held in place.

Therefore, a method that allows for the creation of a low friction coating for the top surface of a platen that does not significantly reduce the clamping force at elevated temperatures would be beneficial.

### SUMMARY

A method of preparing an electrostatic platen is disclosed. At high temperatures, some low friction coatings, such as diamond like carbon (DLC), become conductive. The methods described allow the deposition of a limited amount of DLC to those regions of the electrostatic platen that contact the workpiece. By limiting the amount of DLC applied to the electrostatic platen, the clamping force experienced by the workpiece is minimally affected by the increased conductivity of the DLC at elevated temperatures. The DLC is applied to embossments that extend upward from the flat surface of the electrostatic platen.

According to one embodiment, a method of preparing an electrostatic platen is disclosed. The method comprises performing a patterned deposition of a low friction coating to a top surface of the electrostatic platen such that the low friction coating is applied on embossments disposed on the top surface of the electrostatic platen. In some embodiments, a diffusion barrier layer is deposited prior to the patterned deposition of the low friction coating. In some embodiments, the low friction coating comprises diamond like carbon. In some embodiments, the patterned deposition comprises depositing the low friction coating through a shadow mask using a chemical vapor deposition (CVD) process. In certain embodiments, the chemical vapor deposition (CVD) process comprises plasma assisted CVD (PACVD) or plasma enhanced CVD (PECVD). In certain embodiments, the shadow mask comprises apertures that are aligned with the embossments during the chemical vapor deposition (CVD) process. In certain embodiments, dimensions and a shape of the apertures in the shadow mask are optimized to control a spread of the low friction coating during the chemical vapor deposition (CVD) process. In certain embodiments, sides of the shadow mask that define the apertures comprise a first portion that is angled and a second portion that is vertical.

According to another embodiment, a method of preparing an electrostatic platen is disclosed. The method comprises applying a photoresist to a flat surface of the electrostatic platen, wherein embossments extend upward from the flat surface; depositing a low friction coating to an entirety of a top surface of the electrostatic platen; and lifting off the photoresist and any low friction coating disposed thereon, such that the low friction coating remains on the embossments. In some embodiments, a diffusion barrier layer is deposited prior to applying the photoresist. In some embodiments, the low friction coating comprises diamond like carbon. In some embodiments, the depositing is performed using a chemical vapor deposition (CVD) process. In certain embodiments, the chemical vapor deposition (CVD) process comprises plasma assisted CVD (PACVD) or plasma enhanced CVD (PECVD). In some embodiments, the photoresist is lifted off using a solvent. In some embodiments, the low friction coating remains on a top surface and sidewalls of the embossments.

### BRIEF DESCRIPTION OF THE FIGURES

For a better understanding of the present disclosure, reference is made to the accompanying drawings, which are incorporated herein by reference and in which:

FIGS. 1A-1C shows a side view, a top view and an expanded side view of the platen with the patterned coating, respectively according to one embodiment;

FIG. 2 shows a flow chart for creating the patterned coating;

FIGS. 3A-3B show the process of creating a patterned coating according to one embodiment; and

FIGS. 4A-4D show the process of creating a patterned coating according to a second embodiment.

### DETAILED DESCRIPTION

As noted above, at high temperatures, a diamond like carbon coating on the top surface of the platen may be problematic. As the temperature increases, the conductivity of the DLC coating increases, reducing the clamping force available to the workpiece.

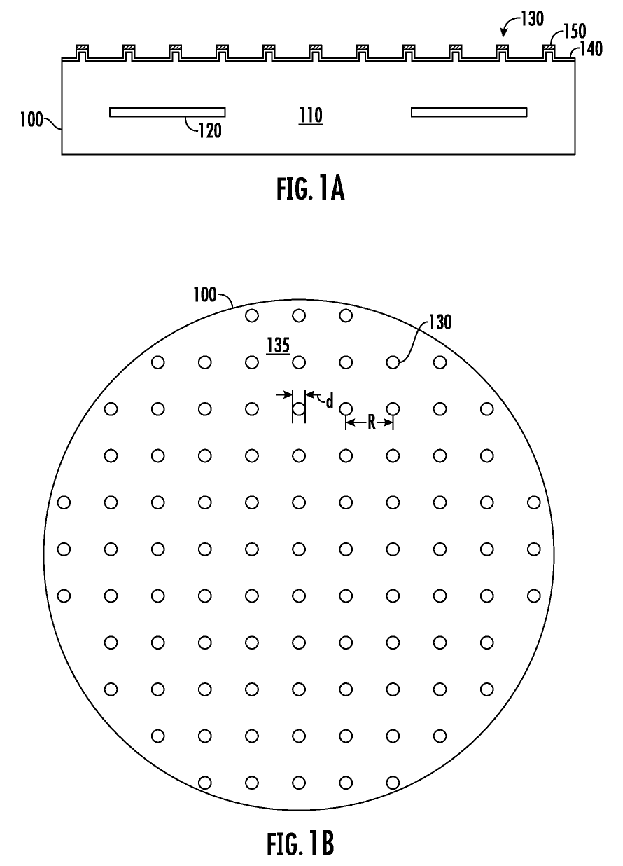

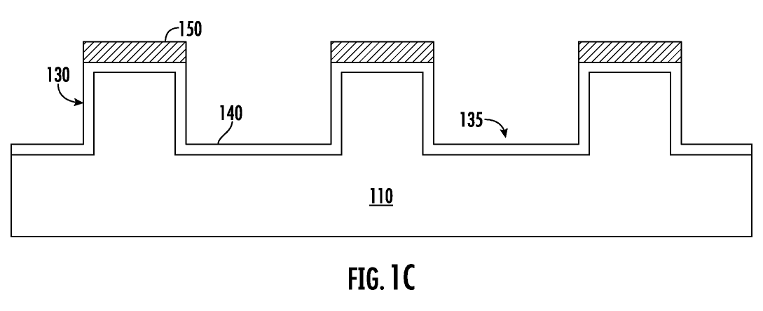

FIGS. 1A-1C show an electrostatic platen 100 that may be used to address this issue. FIG. 1A is a cross-sectional view of the electrostatic platen 100, FIG. 1B is a top view, and FIG. 1C is an expanded cross-sectional view of a portion of the electrostatic platen 100.

The electrostatic platen 100 includes a dielectric material 110, which comprises the body of the platen. The dielectric material 110 may be alumina, although other materials may also be used. One or more electrodes 120 are embedded in the dielectric material.

The top surface of the electrostatic platen 100 includes a plurality of embossments 130. As shown in FIG. 1B, these embossments 130 may have a cylindrical shape, and may be disposed at regular intervals. For example, each embossment 130 may have a diameter, d, which is much smaller than the spacing between adjacent embossments 130, referred to as R. In certain embodiments, the diameter of each embossment 130 may be between 1 and 2 mm, for example, while the spacing between adjacent embossments may be between 3 and 8 mm, as an example. Thus, in some embodiments, the ratio d/R may be less than or equal to 1/2. In some embodiments, the ratio d/R may be 1/4 or less. In certain embodiments, these embossments 130 may be square, rectangular, oval or another shape. These embossments 130 extend upward from the surface of the dielectric material 110 by about 5-15 mm. In this disclosure, the portion of the top surface of the electrostatic platen 100 that does not include the embossments 130 may be referred to as the flat surface 135 of the electrostatic platen 100.

As best seen in FIG. 1C, in some embodiments, a diffusion barrier layer 140 is disposed on the top of the electrostatic platen 100, including on the top surface and side walls of the embossments 130, as well as the flat surface 135 of the electrostatic platen 100. This diffusion barrier layer 140 may be used to limit the diffusion of materials, such as metals, from the dielectric material 110 to the workpiece. This diffusion barrier layer 140 may be an insulating material, such as Si₃N₄. Alternatively, different insulating materials, such as Al₂O₃, SiN_{x,} TiN, Ta₂O₅, or diamond like carbon (DLC), may be used. The thickness of this diffusion barrier layer 140 may be between 0.2 and 2.0 μm, although other thicknesses may be used.

Since the workpiece will rest on the top surfaces of the embossments 130, it is the embossments which are to be coated with the low friction coating 150, which may be diamond like carbon (DLC). Thus, as seen in FIGS. 1A and 1C, the top surface of the embossments 130 is coated with a layer of diamond like carbon. This layer of DLC may be between 0.2 and 1.0 μm, although other thicknesses may be used. In certain embodiments, the low friction coating 150 may also be applied to the side walls of the embossments 130.

Therefore, unlike traditional platens, where the low friction coating 150 is applied to the entirety of the top of the platen, which includes the top surface of the embossments 130 and the flat surface 135 of the electrostatic platen 100, in this embodiment, the low friction coating 150 is applied to the embossments 130. This significantly reduces the amount of DLC that is present on the top of the electrostatic platen 100.

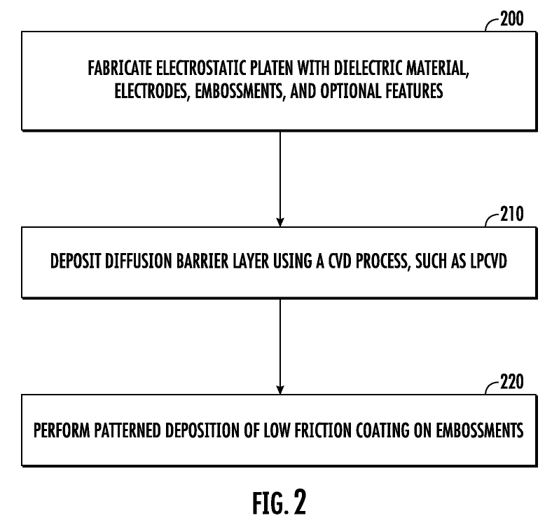

The electrostatic platen 100 of FIGS. 1A-1C may be fabricated in several ways. A flowchart of this fabrication sequence is shown in FIG. 2.

First, as shown in Box 200, an electrostatic platen is fabricated. This fabrication includes the embedding of the electrodes 120, as well as inclusion of any fluid or gas channels. Additionally, any heating or cooling elements may also be embedded in the dielectric material 110 at this time. The top surface of the electrostatic platen 100 also includes the embossments 130.

Next, as shown in Box 210, a diffusion barrier layer 140 is deposited on top of the electrostatic platen 100. This includes the top surfaces and side walls of the embossments 130, as well as the flat surface 135 of the electrostatic platen 100. This may be done using low pressure chemical vapor deposition (LPCVD) or plasma enhanced chemical vapor deposition (PECVD). Low pressure CVD operates at low pressures, such as less than 1 torr to improve uniformity. Additionally, this process is typically carried out at temperatures between 700°C and 850°C to deposit the film.

Finally, as shown in Box 220, a patterned deposition process is performed to deposit the low friction coating 150 on the embossments 130. In other words, the low friction coating 150 is not applied to the flat surface 135 of the electrostatic platen 100. However, it is understood that some amount of low friction coating 150 may be disposed on the flat surface 135 as a result of the patterned deposition process. For example, the low friction coating 150 may be disposed in an annular region around each embossment 130. However, the radius of this annular region may be sufficiently small so as not to substantially reduce the clamping force. For example, the radius of this annular region may be small enough such that the clamping force experienced by the workpiece is reduced by less than 50%. In other embodiments, the clamping force experienced by the workpiece is reduced by less than 25%. In certain embodiments, the radius of the annular region is less than the diameter of the embossment 130.

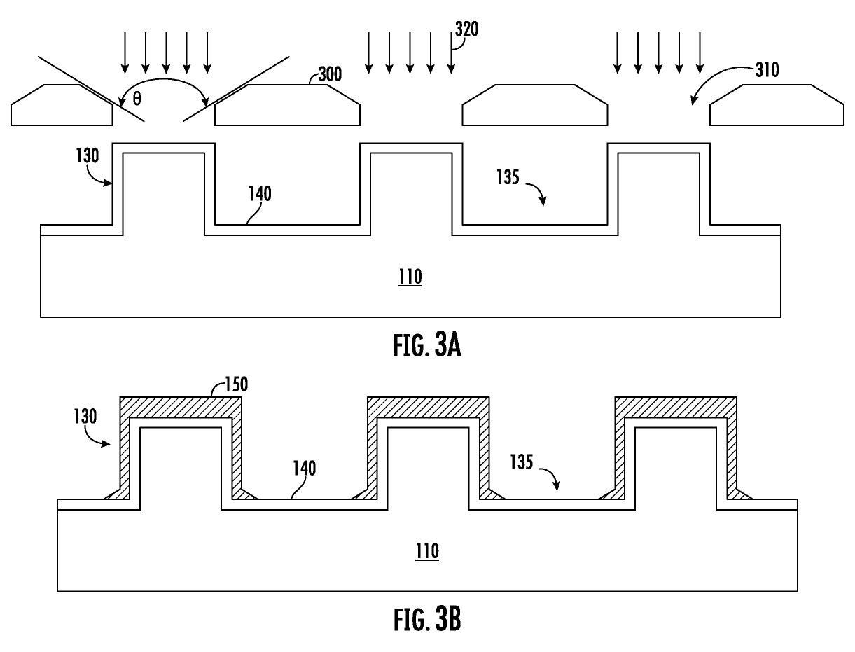

This patterned deposition process may be performed in a number of different ways. According to one embodiment, shown in FIG. 3A, a shadow mask 300 is disposed above the electrostatic platen 100, wherein the apertures 310 in the shadow mask 300 align with the embossments 130. The apertures 310 may be the same diameter as the embossments 130, or may be slightly larger, such as up to 15% larger. In some embodiments, the diameters of the apertures 310 are up to 5% larger than the diameter of the embossments 130. The shadow mask 300 may be made of alumina, aluminum nitride, or other dielectric materials. A typical thickness of the shadow mask 300 may be 1-2mm, although other thicknesses are also possible. Then, using a chemical vapor deposition (CVD) process, such as plasma assisted CVD (PACVD) or plasma enhanced CVD (PECVD), the low friction coating 150 may be applied to the top surfaces of the embossments 130. PECVD allows the creation of this DLC layer by ionizing a species 320 comprising hydrocarbons to form a film having more than about 60-70% sp3 carbon bonds. In order to control the thickness uniformity, the spread of the coating, and the adhesion to the embossments 130, the dimensions and shape of the apertures 310 in the shadow mask 300 may be optimized. For example, as shown in FIG. 3A, a portion of the sides of the shadow mask 300 that define the apertures 310 may be angled. For example, a first portion of the sides may define an angle θ. A second portion of the sides, which may be the portion closest to the platen, may be vertical. The deposition process is controlled by “line of sight”. By tapering the first portion of the sides to create the angle θ, the amount of the top surface of the embossments 130 that is exposed to the deposition material may be tailored. Similarly, the thickness of the first portion may also affect thickness uniformity of the low friction coating 150. Once the desired thickness, which may be between 0.2μm and 1μm in some embodiments, and spread of the low friction coating 150 is achieved, the process may terminate. The alignment of the apertures 310 in the shadow mask 300 may ensure minimal deposition of low friction coating 150 on the flat surfaces 135, as shown in FIG. 3B. Of course, as described above, some of the low friction coating 150 may be disposed on the flat surface 135 around each embossment 130.

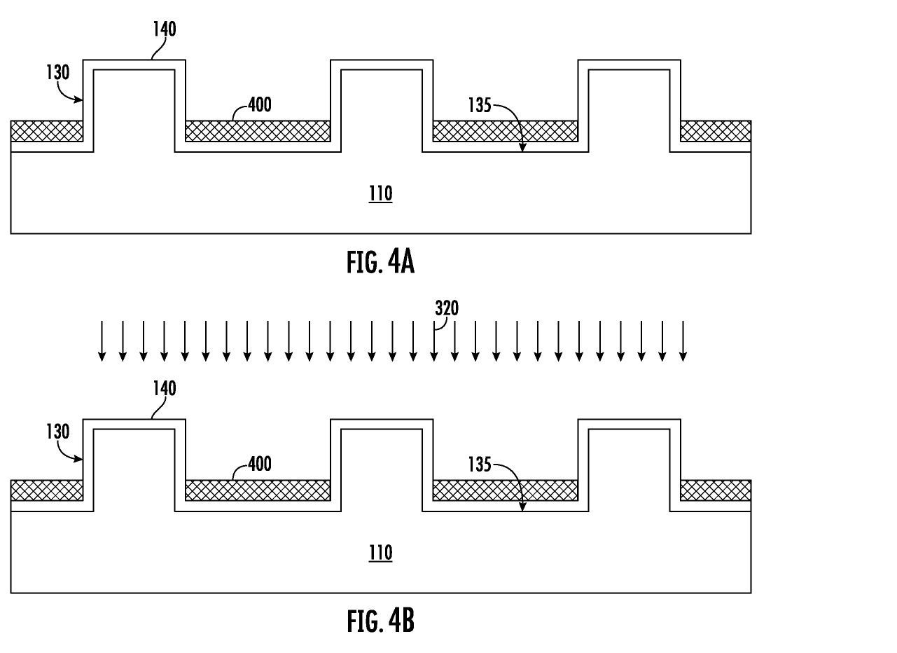

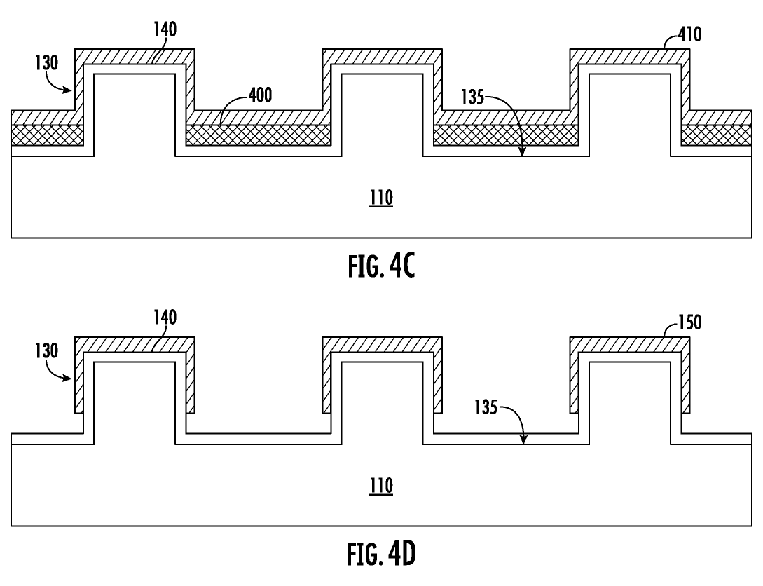

FIGS. 4A-4D show a second sequence that may be used to apply the low friction coating 150 to the top surface of the embossments 130. First, as shown in FIG. 4A, a photoresist 400 is applied to the flat surface 135 of the electrostatic platen 100. This photoresist may be any traditional photoresist material, such as PMMA, DNQ-novolac, or another suitable material, and may have a thickness of 1-2 μm. The photoresist 400 is not deposited on the top surface of the embossments 130. Note that, in certain embodiments, the diffusion barrier layer 140 is deposited prior to the applying of the photoresist 400. As described above, the diffusion barrier layer 140 may be applied to the entirety of the top surface of the platen, including the flat surface 135 and the embossments 130.

Next, as shown in FIG. 4B, using a chemical vapor deposition process, such as plasma assisted CVD (PACVD) or plasma enhanced CVD (PECVD), the low friction coating 150 may be applied to the top of the electrostatic platen 100. PECVD allows the creation of this DLC layer by ionizing a species 320 comprising hydrocarbons to form a film having a large number of sp3 carbon bonds, such as more than about 60%. Once the desired thickness of the low friction coating is achieved, the process may terminate. As shown in FIG. 4C, this results in a layer 410 of low friction coating deposited on the top of the electrostatic platen 100, including on top of the embossments 130, as well as on top of the photoresist 400.

Finally, as shown in FIG. 4D, the photoresist 400, and the layer 410 of low friction coating deposited thereon, is lifted off the flat surface 135 of the electrostatic platen 100. This may be accomplished by dissolving the photoresist 400 using a solvent. This may result in the low friction coating 150 only being disposed on the embossments 130, as illustrated in FIG. 4D. The low friction coating 150 is present on the top surface of the embossments 130 and may also be present on at least a portion of the side walls of the embossments 130. In certain embodiments, the photoresist 400 may not contact the side wall of each embossment 130, allowing some of the layer 410 to contact the flat surface 135. However, as described above, the radius of the annular region around the embossment 130 which is exposed to the layer 410 may be sufficiently small so as not to adversely impact the clamping force experienced by the workpiece.

Thus, the sequences in FIGS. 3A-3B and 4A-4D both result in the low friction coating 150 being disposed on the embossments 130. This serves to provide the low friction where the workpiece physically contacts the electrostatic platen 100, with minimal effect on the clamping force experienced by the workpiece.

The system and method described herein have many advantages. First, as noted above, the amount of DLC that is deposited on the top of the electrostatic platen 100 is greatly reduced. Specifically, if the diameter of the embossments 130 is defined as d, and the spacing between embossments 130 is defined as R, the fraction of the electrostatic platen 100 that is covered by the low friction coating 150 is given by πd²/4R². If the ratio of d/R is 1/4, then the percentage of the electrostatic platen 100 that is covered by the DLC is less than 5%, if the low friction coating is disposed only on the embossments 130. This small percentage has minimal impact on the clamping force experienced by the workpiece. Furthermore, even if some of the low friction coating 150 becomes deposited on the flat surface 135 of the electrostatic platen 100, the clamping force experienced by the workpiece will still be sufficient to hold the workpiece in place. It is well known that DLC may become electrically conductive when heated to temperatures above 500°C, which could greatly reduce the ability of the electrostatic platen 100 to clamp a workpiece if a blanket coating of DLC is applied. Using this embodiment, however, the effects of DLC on the clamping force are minimal, especially when the platen is at temperatures above 500°C. Furthermore, the processes described herein do not etch the top surface of the electrostatic platen 100, so no damage is done to the diffusion barrier layer or the dielectric material. Consequently, no additional polishing or buffing processes are performed and the integrity of the surface of the platen is maintained.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of preparing an electrostatic platen, comprising:
performing a patterned deposition of a low friction coating to a top surface of the electrostatic platen such that the low friction coating is applied on embossments disposed on the top surface of the electrostatic platen.

2. The method of claim 1, further comprising depositing a diffusion barrier layer prior to the patterned deposition of the low friction coating.

3. The method of claim 1, wherein the low friction coating comprises diamond like carbon.

4. The method of claim 1, wherein the patterned deposition comprises depositing the low friction coating through a shadow mask using a chemical vapor deposition (CVD) process.

5. The method of claim 4, wherein the chemical vapor deposition (CVD) process comprises plasma assisted CVD (PACVD) or plasma enhanced CVD (PECVD).

6. The method of claim 4, wherein the shadow mask comprises apertures that are aligned with the embossments during the chemical vapor deposition (CVD) process.

7. The method of claim 6, wherein dimensions and a shape of the apertures in the shadow mask are optimized to control a spread of the low friction coating during the chemical vapor deposition (CVD) process.

8. The method of claim 7, wherein sides of the shadow mask that define the apertures comprise a first portion that is angled and a second portion that is vertical.

9. A method of preparing an electrostatic platen, comprising:
applying a photoresist to a flat surface of the electrostatic platen, wherein embossments extend upward from the flat surface;
depositing a low friction coating to an entirety of a top surface of the electrostatic platen; and
lifting off the photoresist and any low friction coating disposed thereon, such that the low friction coating remains on the embossments.

10. The method of claim 9, further comprising depositing a diffusion barrier layer prior to applying the photoresist.

11. The method of claim 9, wherein the low friction coating comprises diamond like carbon.

12. The method of claim 9, wherein the depositing is performed using a chemical vapor deposition (CVD) process.

13. The method of claim 12, wherein the chemical vapor deposition (CVD) process comprises plasma assisted CVD (PACVD) or plasma enhanced CVD (PECVD).

14. The method of claim 9, wherein the photoresist is lifted off using a solvent.

15. The method of claim 9, wherein the low friction coating remains on a top surface and sidewalls of the embossments.
